(19) United States
(12) Patent Application Publication
(10) Pub. No.: US 2024/0097087 A1
(43) Pub. Date: Mar. 21, 2024

(54) Method of Transferring Patterned Micro-LED Die onto a Silicon Carrier for Wafer-to-Wafer Hybrid Bonding to a CMOS Backplane

(71) Applicant: Apple Inc., Cupertino, CA (US)

(72) Inventors: Justin S. Brockman, Palo Alto, CA (US); Fang Ou, San Jose, CA (US); Lina He, San Jose, CA (US); Dmitry S. Sizov, Cupertino, CA (US); Lei Zhang, Albuquerque, NM (US)

(21) Appl. No.: 18/450,664

(22) Filed: Aug. 16, 2023

Related U.S. Application Data
(60) Provisional application No. 63/376,039, filed on Sep. 16, 2022.

(51) Int. Cl. H01L 33/62; H01L 25/075; H01L 25/16; H01L 33/00; H01L 33/10

(52) U.S. Cl. CPC H01L 33/62; H01L 25/0753; H01L 25/167; H01L 33/0093; H01L 33/10; H01L 2933/0066

(57) ABSTRACT

Optoelectronic structures and methods of formation are described. In an embodiment, an optoelectronic structure includes a backplane with a driving circuitry and an array of contact pads, and a device layer bonded to the backplane. The device layer may include an array of micro-sized diodes and landing pads, and a reconstituted wiring layer including an array of via contacts connected to the array of landing pads. The reconstituted wiring layer can be directly bonded with the array of contacts with metal-metal bonds. A placement distribution of the array of landing can be decoupled from a position distribution of the array of via contacts.

### RELATED APPLICATIONS

This application claims the benefit of priority of U.S. Provisional Application No. 63/376,039 filed Sep. 16, 2022, which is incorporated herein by reference.

### BACKGROUND

### FIELD

Embodiments described herein relate to optoelectronic structures. More specifically, embodiments relate to optoelectronic structures with micro-sized light emitting or sensing diodes.

### Background Information

State of the art displays for portable electronics, computers, and televisions commonly utilize glass substrates with thin film transistors (TFTs) to control transmission of backlight through pixels based on liquid crystals. More recently emissive displays such as those based on organic light emitting diodes (OLEDs) have been introduced. Even more recently, it has been proposed to integrate emissive inorganic semiconductor-based micro LEDs into displays. Micro LED integration however can require mass transfer techniques of micro LEDs from growth substrates based on non-silicon materials, such as sapphire, gallium nitride, etc. In one implementation it has been proposed to perform mass transfer utilizing an array of transfer heads. In other implementations it has been proposed to perform mass transfer with wafer bonding techniques.

### SUMMARY

In an embodiment, an optoelectronic structure includes a backplane with a driving circuitry and an array of contact pads, and a device layer bonded to the backplane. The device layer may include an array of micro-sized diodes and landing pads, and an array of via contacts connected to the array of landing pads. The array of via contacts can be part of a reconstituted wiring layer that is directly bonded with the array of backplane contact pads with metal-metal bonds. A placement distribution of the array of landing pads can be decoupled from a position distribution of the array of via contacts through a reconstitution process, where a reconstituted substrate is formed that is then bonded to the backplane.

In an embodiment, a method of assembling an optoelectronic structure includes patterning an array of micro-sized diodes into a p-n diode layer on a growth substrate, forming an array of landing pads on top of the array of micro-sized diodes, transferring the array of micro-sized diodes and the array of landing pads to a first carrier substrate, singulating the array of micro-sized diodes, the array of landing pads, and the first carrier substrate into a plurality of coupons, each coupon including a sub-array of micro-sized diodes and sub-array of landing pads, reconstituting an array of coupons on a second carrier substrate to form a reconstituted substrate, hybrid bonding the reconstituted substate to a backplane, and singulating a plurality of optoelectronic structures.

In an embodiment, the micro-sized diode carrier substrate which is singulated includes a silicon or sapphire wafer, and the reconstituted substrate and backplane each includes a silicon wafer. Reconstituting the array of coupons on the second carrier substrate can include die-to-wafer bonding the array of coupons to the second carrier substrate. Hybrid bonding the reconstituted substrate to the backplane may include wafer-to-wafer bonding.

The optoelectronic structures and methods of fabrication can overcome several challenges associated with bonding of high density arrays of micro-sized diodes to a backplane, including allowing for high temperature processing of the micro-sized diodes to be completed on a growth substrate, mitigation of particle contamination during dicing by not dicing through the growth substrates, testing of known good dies, reducing coefficient of thermal expansion (CTE) risk during die-to-wafer bonding with a silicon-silicon system, loosening of die-to-wafer alignment tolerance with oversized landing pads, and decoupling wafer-to-wafer bond alignment from die-to-wafer bond alignment.

### BRIEF DESCRIPTION OF THE DRAWINGS

FIG. 1 is a cross-sectional side view illustration of a micro-sized diode reconstitution and wafer-to-wafer bonding sequence in accordance with an embodiment.

FIG. 2 is a schematic top view illustration of an optoelectronic structure with a misaligned coupon in accordance with an embodiment.

FIG. 3 is a schematic cross-sectional side view illustration of an optoelectronic structure in accordance with an embodiment.

FIG. 4A is a schematic cross-sectional side view illustration of an optoelectronic structure stack-up including a micro-sized diode with a diffused sidewall passivation layer in accordance with an embodiment.

FIGS. 4B-4C are schematic cross-sectional side view illustrations of an optoelectronic structure stack-up including a micro-sized diode with a regrown sidewall passivation layer in accordance with an embodiment.

FIG. 5A is a schematic cross-sectional side view illustration of an optoelectronic structure including multiple coupons in accordance with an embodiment.

FIG. 5B is a close-up schematic cross-sectional side view illustration of an optoelectronic structure including a single coupon in accordance with an embodiment.

FIG. 5C is a schematic top view illustration of the top opaque electrode layer of FIG. 5B in accordance with an embodiment.

FIGS. 6A-6N are cross-sectional side view illustrations of a micro-sized diode reconstitution and wafer-to-wafer bonding sequence in accordance with an embodiment.

FIGS. 7A-7L are cross-sectional side view illustrations of a micro-sized diode reconstitution and wafer-to-wafer bonding sequence in accordance with an embodiment.

### DETAILED DESCRIPTION

Embodiments described optoelectronic structures and methods of fabrication in which high densities of micro-sized diodes (such as micro LEDs or photodetectors) can be bonded to a substrate, such as a complementary metal-oxide-semiconductor (CMOS) substrate or substrate including an array of pixel driver chips, at high pixel densities and landing pad pitch. For example, embodiments may be utilized to produce pixel densities greater than 5,000 ppi and backplane landing pad pitch of 5 μm or less. This can be achieved using a reconstitution process in which micro LED arrays from growth substrates are transferred to a synthetic silicon carrier wafer and reconstituted to form via contacts as part of a reconstituted wiring layer, followed by wafer-to-wafer bonding to a CMOS substrate (or substrate including an array of pixel driver chips), and final singulation of the optoelectronic structures. Furthermore, embodiments may overcome several challenges involved in the various bonding processes including wafer size mismatch, coefficient of thermal expansion (CTE) mismatch induced bonding stresses, yield fallout due to dicing particles, yield fallout due to bonding mis-alignment, and thermal budget.

As used herein the term “micro-sized diodes” or “micro LEDs” may refer to the maximum lateral dimension of the device. In some embodiments, the “micro” sized diodes may have a maximum lateral dimension below 100 μm, such as below 10 μm, such as 5 μm, 0.5 μm, or less. In a specific embodiment, the micro LEDs have a maximum lateral dimension of 1 μm. The processing sequences in accordance with embodiments may be used to form both monochromatic and full color optoelectronic structures such as displays and sensors.

In an exemplary embodiment, an optoelectronic structure and process flow are described for reconstituting coupons (or dies) of patterned micro LED device arrays onto a synthetic 300 mm silicon carrier to prepare these dies for 300 mm copper damascene processing and 300 mm wafer-to-wafer hybrid bonding to a CMOS backplane wafer. Such a process flow can allow for very high-temperature sidewall passivation processes to be performed on the initial LED growth substrate, relaxed criteria for die-to-wafer bonding placement accuracy, and higher product yields due to leveraging mature 300 mm wafer copper damascene and 300 mm wafer-to-wafer bonding to a CMOS backplane wafer to create the final electrical connections to the micro LED devices. While embodiments described herein are made with regard to micro LED devices it is understood that embodiments are also applicable to other devices such as photodetectors, for example for sensor array. Furthermore, while embodiments are described with regard to 300 mm wafer processes, this is exemplary for state-of-the-art silicon processing facilities, and embodiments are not so limited. In addition, while embodiments are described with regard to silicon CMOS backplane wafers it is to be appreciated that alternative backplane structures may be utilized such as a backplane substrate including an array of embedded silicon pixel driver chips and electrical routing that support similar function as a monolithic silicon CMOS backplane.

Regarding wafer size mismatch, substrates used for micro LED device fabrication (e.g. 100 mm, 150 mm, 200 mm wafers) may currently be smaller than those used for highest performance and latest design CMOS technology nodes (e.g. 300 mm wafers). In accordance with embodiments, dicing of the growth substrate and direct die-to-wafer bonding to the larger CMOS wafer is avoided through the reconstitution process.

Regarding CTE mismatched induced bonding stresses, two substrates used for micro LED epitaxy commonly include GaAs and sapphire, both of which have a CTE factor roughly double that of silicon. It has been observed this CTE factor difference can cause die/wafer warpage during bonding and also contribute to bonding misalignments. In accordance with embodiments this is mitigated through the reconstitution process before wafer-to-wafer bonding to a CMOS backplane wafer (or substrate including an array of embedded pixel driver chips).

Regarding yield fallout due to dicing particles, achieving zero dead pixels on the final product may require extremely high die-to-wafer or wafer-to-wafer contact pad bonding yield. This can require flat and particle-free surfaces at the time of bonding, particularly for die-to-wafer bonding steps where particles and debris generated during dicing must be mitigated or fully removed in a cleaning step prior to bonding. In an embodiment avoidance of dicing particles can be mitigated through a reconstitution process in which a diced growth substrate (e.g. GaAs, sapphire) is not bonded to a backplane substrate (e.g. CMOS wafer or substrate including an array of pixel driver chips). In accordance with embodiments the growth substrate may be removed prior to any dicing.

Regarding fallout due to bonding mis-alignment, embodiments facilitate implementation of fine pitch density that can approach state-of-the-art limitations of die-to-wafer and wafer-to-wafer bonding. In an embodiment, this is achieved with a wafer reconstitution method in which oversized landing pads are formed on each micro LED on the LED growth substrate prior to dicing coupons (dies). The LED coupons are then reconstituted on a 300 mm silicon wafer, where an array of via contacts are formed to connect to the array of oversized landing pads. The reconstituted wafer is then bonded to a backplane substrate (e.g. CMOS wafer or substrate including an array of pixel driver chips). In this manner the wafer-to-wafer bond alignment is decoupled from the die-to-wafer process.

Regarding thermal budget, in some embodiments a high temperature (e.g. greater than 400° C.) micro LED sidewall passivation process or a high temperature p/n contact formation anneal is needed for device performance and electrical contact reasons. In one aspect, it has been observed that in order to achieve high-brightness and high-efficiency micro LEDs that Shockley-Read-Hall (SRH) non-radiative recombination effects at the device sidewalls can be addressed. For example, it has been observed that SRH recombination can be mitigated by various high temperature processing techniques such as sidewall diffusion (e.g. zinc, magnesium, carbon, silicon, tellurium, etc.) at elevated temperatures or semiconductor regrowth deposition at elevated temperatures. In this case the micro LED device layers and substrate need to be compatible with the high temperature. However, a maximum allowed temperature for a backplane substrate (e.g. CMOS wafer or substrate including an array of pixel driver chips) can be approximately 400° C. due to the temperature stability of low-k interlayer dielectrics. Furthermore, it has been observed if epitaxial LED layers have been bonded to a new carrier substrate there can be concern of CTE mismatch between the epitaxial layers and the new carrier substrate during any subsequent high temperature exposures. Lastly, it has been observed that thermal budget and/or outgassing of the bonding materials (which are typically annealed at temperatures less than 400° C. at the time of wafer bonding) can be a concern. In accordance with embodiments micro LED sidewall passivation or high temperature p/n contact formation anneal may be performed on the initial LED growth substrates as opposed to a silicon substrate due to coefficient of thermal expansion (CTE) mismatch between the epitaxial LED device layers and silicon, and to avoid outgassing or bond-line voids that can occur with many bonding layers used for epitaxial layer transfer when subjected to post-bond processing temperatures above 400° C.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “above”, “over”, “to”, “between”, “spanning” and “on” as used herein may refer to a relative position of one layer with respect to other layers. One layer “above”, “over”, “spanning” or “on” another layer or bonded “to” or in “contact” with another layer may be directly in contact with the other layer or may have one or more intervening layers. One layer “between” layers may be directly in contact with the layers or may have one or more intervening layers.

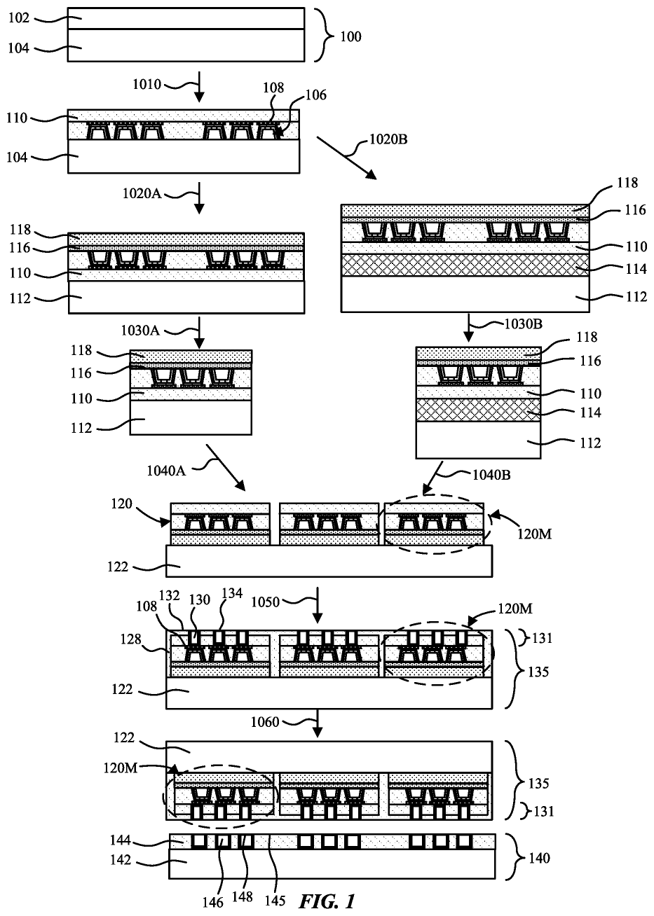

Referring now to FIG. 1 a cross-sectional side view illustration is provided of a micro-sized diode reconstitution and wafer-to-wafer bonding sequence in accordance with an embodiment. In the following description, various operations are referred to which illustrate various milestones of wafer flipping or die-to-wafer or wafer-to-wafer bonding in the process sequence. Thus, many processes may have occurred between each operation, or milestone.

As shown, the processing sequence can begin with a bulk LED substrate 100 including a p-n diode layer 102 formed on a growth substrate 104. For example, the p-n diode layer 102 may be designed for emission of primary red light (e.g. 600-700 nm wavelength), primary green light (e.g. 495-570 nm wavelength), or primary blue light (e.g. 450-495 nm wavelength), though embodiments are not limited to these exemplary emission spectra. The p-n diode layer 102 may be formed of a variety of compound semiconductors having a bandgap corresponding to a specific region in the spectrum. For example, the p-n diode layer 102 can include one or more layers based on II-VI materials (e.g. ZnSe) or III-V materials including III-V nitride materials (e.g. GaN, InN, InGaN, and their alloys), III-V phosphide materials (e.g. GaP, AlGaInP, and their alloys), and III-V arsenide alloys (AlGaAs). The growth substrate 104 may include any suitable substrate such as, but not limited to, SiC, GaAs, GaN, sapphire, and silicon.

By way of example, in an embodiment the p-n diode layer 102 is designed for emission of red light, and the materials are phosphorus based. The followed listing of materials for red emission is intended to be exemplary and not limiting. For example, the layers forming the p-n diode layer 102 may include AlInP, AlInGaP, AlGaAs, GaP, and GaAs. In such an embodiment, a suitable growth substrate 104 may include, but not limited to, SiC and GaAs. In a specific embodiment, the growth substrate is a 100 mm, 150 mm or 200 mm GaAs substrate.

By way of example, in an embodiment, the p-n diode layer 102 is designed for emission of blue or green light, and the materials are nitride based. The following listing of materials for blue or green emission is intended to be exemplary and not limiting. For example, the layers forming the p-n diode layer 102 may include GaN, AlGaN, InGaN. In such an embodiment, a suitable growth substrate 104 may include, but is not limited to, sapphire. In a specific embodiment, the growth substrate is a 100 mm, 150 mm or 200 mm sapphire substrate.

At operation 1010 the p-n diode layer 102 is patterned to form an array of micro-sized diodes 106, landing pads 108 and a backside dielectric layer 110. Numerous additional structures and processes may be performed. The growth substrate can then be flipped and bonded onto another carrier and prepared for dicing into coupons (or dies) for reconstitution. In this manner particles can be reduced by first removing the growth substrate 104. In a first variation, at operation 1020A the backside dielectric layer 110 is bonded to a carrier substrate 112 such as a 100 mm, 150 mm, or 200 mm silicon substrate. The carrier substrate 112 may be the same size as the original growth substrate 104 so that wafer-to-wafer bonding techniques are used. In an embodiment, bonding is achieved by oxide-oxide direct bonding followed by post bond anneal. The growth substrate 104 is then removed using a suitable technique such as wet etch and chemical mechanical polishing (CMP), laser lift off (LLO), etc. This can be followed by deposition of a top contact layer 116, which may be a transparent conductive oxide, such as indium tin oxide (ITO), or transparent conductive polymer. The top contact layer 116 may then be covered with a protective dielectric layer 118, which may also be transparent. In an embodiment, the carrier substrate 112 of the first variation is a sapphire wafer. In the second variation, at operation 1020B the backside dielectric layer 110 is instead bonded to the carrier substrate 112 with a curable bonding layer 114, such as benzocyclobutene (BCB). Curing can be thermal based, or UV-based for more CTE-mismatched material systems. This can be followed by deposition of a top contact layer 116 and protective dielectric layer 118. In an embodiment, the carrier substrate 112 of the second variation is a sapphire wafer.

For both variations, at operation 1030A and 1030B the light emitting structure is diced into coupons 120 (also referred to as dies). As shown, the growth substrate 104 has been removed at this point, and therefore the process flow eliminates introduction of growth substrate 104 particles that would be generated during dicing into subsequent facilities. Exemplary dicing methods include saw dicing, stealth dicing, plasma etch dicing, etc.

Referring now to operations 1040A and 1040B an array of coupons 120 may then be bonded to a second carrier substrate 122. Coupons 120 may have been formed from a plurality of LED substrates 100. Specifically, the second carrier substate 122 may be a silicon wafer, and more specifically a 300 mm silicon wafer that can be processed with current industry standards. As shown the protective dielectric layer 118 is bonded directly to a thin oxide top surface of the second carrier substrate 122 with oxide-oxide bonds after plasma surface activation. This is followed by removal of the first carrier substrate 112. For example, a grinding technique may be used for a silicon first carrier substrate, while a LLO technique may be used for a sapphire first carrier substrate.

Still referring to operations 1040A and 1040B a misaligned coupon 120M is additionally illustrated. As will become apparent in the following description, the reconstitution sequence and oversized landing pads 108 can allow for relaxed tolerances of a placement distribution of the coupons, and hence the array of micro-sized diodes 106.

Referring now to operation 1050 a gap fill layer 128 is formed over and laterally between the coupons 120. For example, the gap fill layer 128 can be an oxide layer or other suitable dielectric. This may be followed by planarization and industry-standard 300 mm copper damascene processing to form one or more metal layers. In the process illustrated single damascene via contacts 130 are formed as part of a reconstituted wiring layer 131 to connect with the landing pads 108. Dual damascene and other processed may also be used to form the reconstituted wiring layer 131. It is to be appreciated that the damascene processing is decoupled from coupon 120 placement by inclusion of the oversized landing pads 108. In the final stage of the copper damascene processing, the reconstituted substrate 135 is processed with CMP to provide a planar dielectric surface 132 and a planar metal contact surface 134 of the reconstituted wiring layer 131, which may correspond to the via contacts 130 or other redistribution layer, etc. within the reconstituted wiring layer 131.

Still referring to operation 1050, the position distribution of via contacts 130 may be defined by the 300 mm copper damascene processing, and therefore untied to the placement distribution of the coupons 120. As shown the oversized landing pads 108 for the misaligned coupon 120M allow for contact with the via contacts 130.

The reconstituted substrate 135 may then be bonded to a backplane 140, such as a CMOS substrate or substrate including a plurality of embedded pixel driver chips, at operation 1060. In accordance with embodiments the bonding may be wafer-to-wafer hybrid bonding. As shown in FIG. 1, the backplane 140 may include a silicon substrate 142 and top dielectric layer 144 with vias 146. A top surface may be planarized to form planarized top contact pads 148 of the vias 146 and planarized top surface 145 of the top dielectric layer 144. In an embodiment, hybrid bonding may achieve metal-metal (e.g. copper-copper) bonds with contact pads 148 and planar contact surfaces 134, and dielectric-dielectric (e.g. oxide-oxide) bonds with planar dielectric surface 132 and top surface 145 of top dielectric layer 144. The second carrier substrate 122 can then be removed, followed by deposition of additional optics and singulation into optoelectronic structures.

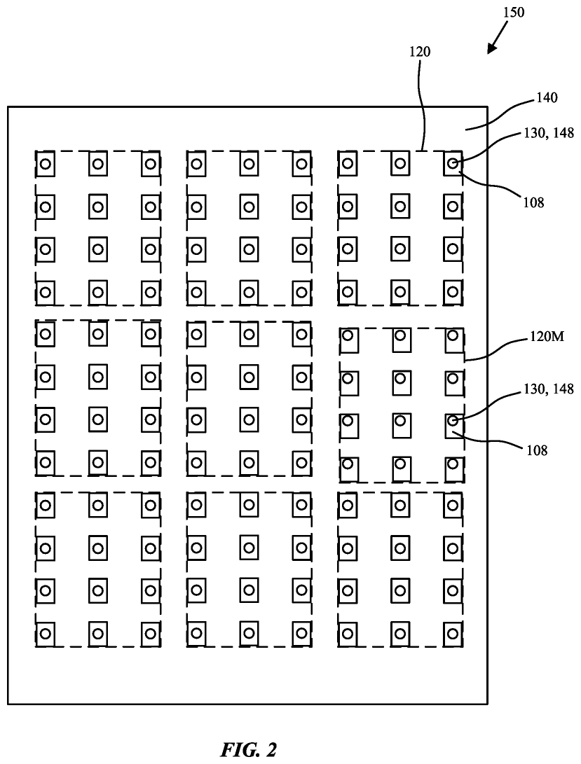

FIG. 2 is a schematic top view illustration of an optoelectronic structure 150 with a misaligned coupon 120M in accordance with an embodiment. Specifically, FIG. 2 illustrates an optoelectronic structure 150 after singulation. As shown, an array of coupons 120, including a mis-aligned coupon 120M are arranged on a backplane 140. The x-y location of the mis-aligned coupon 120M has been shifted from a nominal location, as evidenced by location of the landing pads 108. However, the location of the via contacts 130 and contact pads 148 (illustrated as the same location) are determined with 300 mm copper damascene processing and wafer-to-wafer bonding accuracy, both of which may be higher than the die-to-wafer bonding accuracy of the coupons. In an embodiment, a placement distribution of the array of landing pads 108 across the backplane 140 is characterized by a first order standard deviation of displacement values of the array of landing pads to the array of contact pads 148, and position distribution of the array of via contacts 130 across the backplane is characterized by a first order standard deviation of displacement values of the array of via contacts 130 to the corresponding array of contact pads 148, and the first order standard deviation for the placement distribution of the array of landing pads 108 across the backplane is larger than the first order standard deviation for the position distribution of the array of via contacts 130 across the backplane. In interest of convenience, distributions may be measured from geometrical center (or centroid) points of the structures.

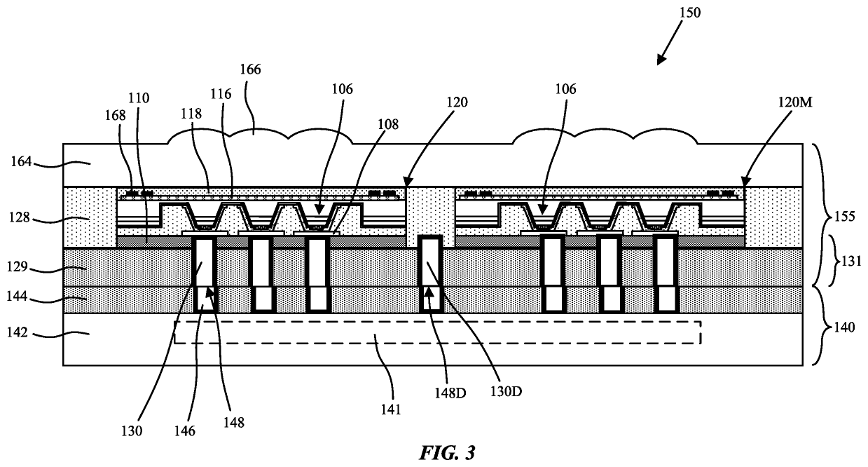

FIG. 3 is a schematic cross-sectional side view illustration of an optoelectronic structure 150 in accordance with an embodiment. In particular, the optoelectronic structure 150 illustrated in FIG. 3 could be fabricated utilizing the process sequence illustrated in FIG. 1. In an embodiment, an optoelectronic structure 150 includes a backplane 140 including driving circuitry 141 (e.g. CMOS driving circuitry, or a pixel driver chip including the driving substrate) and an array of contact pads 148, and a device layer 155 bonded to the backplane 140. The device layer 155 may have been formed as part of a reconstitution process and include an array of micro-sized diodes 106 (e.g. micro LEDs, photodetectors), an array of landing pads 108 underneath the array of micro-sized diodes 106, where each landing pad corresponds to a micro-sized diode, and an array of via contacts 130 connected to the array of landing pads 148, where each via contact 130 corresponds to a landing pad 148. In accordance with embodiments, the array of via contacts 130 is part of a reconstituted wiring layer 131 that is directly bonded with the array of contact pads 148 with metal-metal bonds (e.g. copper-copper).

The array of via contacts 130 may be formed with a damascene process, including single damascene, double damascene. The array of via contacts 130 may be formed as part of a single metal layer or multiple metal layers within the reconstituted wiring layer 131 for routing distribution. In the particular embodiment illustrated a single damascene and single metal layer is shown, though embodiments are not so limited. The array of via contacts 130 may also be embedded within a dielectric build-up layer 129. For example, this may be a part of the gap fill layer 128 or a separate layer formed on top of the gap fill layer 128 and coupons 120 during the reconstitution sequence. As shown, the dielectric build-up layer 129 can be bonded directly to a top dielectric layer 144 of the backplane 140 with dielectric-dielectric bonds (e.g. oxide-oxide).

In accordance with embodiments, the array of micro-sized diodes 106 may be part of a plurality of coupons 120, with each coupon including a sub-array of micro-sized diodes 106. Furthermore, a gap fill layer 128 may laterally surround each coupon 120 and be located laterally between adjacent coupons. Each coupon 120 may include a backside dielectric layer 110. In this manner, the array of via contacts 130 includes a plurality of sub-arrays of via contacts 130, with each sub-array of via contacts extending through a corresponding backside dielectric layer 110. In an embodiment a pitch between the via contacts 130 within each sub-array of via contacts is 5 μm or less, though embodiments are not so limited.

The optoelectronic structure 150 may optionally include a plurality of dummy vias 130D formed at the same time and laterally adjacent to the array of via contacts 130. Dummy vias 130D may extend through the dielectric build-up layer 129, and optionally partially into the gap fill layer 128. Likewise, the backplane 140 may optionally include a plurality of contact pads 148D to facilitate wafer-to-wafer bonding. The plurality of dummy vias 130D may be arranged between the coupons so that they are not directly above the plurality of coupons 120. This may facilitate mechanical and thermal balancing for example, though other arrangements are possible.

Still referring to FIG. 3 in accordance with embodiments after removal of the second carrier substrate 122 additional processing can be performed, such as final power and data routing, as well as formation of additional optical features such as micro lens fabrication. In an embodiment, micro lenses are formed by deposition of an optical layer 164, followed by imprinting to form half ball features 166 or similar. Additional features shown but not labeled in FIG. 3, such as the alignment keys 168, will be described in more detail in the following description.

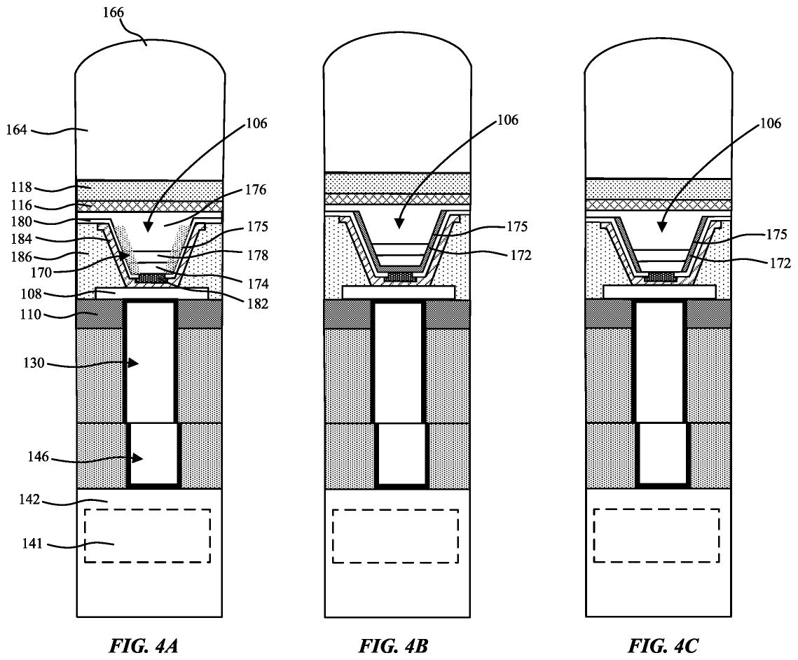

Referring now to FIGS. 4A-4C, FIG. 4A is a schematic cross-sectional side view illustration of an optoelectronic structure stack-up including a micro-sized diode 106 with a diffused sidewall passivation layer 170 in accordance with an embodiment; FIGS. 4B-4C are schematic cross-sectional side view illustrations of an optoelectronic structure stack-up including a micro-sized diode with a regrown sidewall passivation layer 172 in accordance with an embodiment. In the exemplary embodiments illustrated each micro-sized diode 106 may include a bottom doped layer 174 (e.g. p-doped), a top doped layer 176 (e.g. n-doped) with an opposite doping than the bottom doped layer, and an active layer 178 between the bottom doped layer and the top doped layer. For example, the active layer 178 may include one or more quantum well layers and barrier layers separating the quantum well layers.

A dielectric insulation layer 180 may be formed over, along sidewalls 175 and between the micro-sized diodes 106 to provide electrical insulation. An opening may be formed in the dielectric insulation layer 180 on the bottom side of the bottom doped layer 174 to allow a bottom electrical contact 182 to make electrical contact with the bottom doped layer 174 (or some intervening current spreading layer). The bottom electrical contact 182 may be a single layer, or multiple metal layer stack for example. A reflector layer 184 may optionally be formed on the dielectric insulation layer 180, and optionally the bottom electrical contact 182. The reflector layer 184 may be formed of a suitable material (e.g. Au, Ag, Al, Ru, etc.) to reflect a peak emission/absorption wavelength of the micro-sized diode 106. In the illustrated embodiments, the landing pad 108 is formed directly on the reflector layer 184. A dielectric fill layer 186 may be located around the micro-sized diode 106, and optionally landing pad 108. The dielectric fill layer 186 may be formed of a suitable material such as BCB and may be transparent or opaque.

In the particular embodiment illustrated in FIG. 4A the diffused sidewall passivation layer 170 may be formed by a thermal plasma or ion implantation technique for example. In an embodiment, a dopant such as zinc, magnesium, carbon, silicon, tellurium, etc. is diffused into the sidewalls 175 to facilitate intermixing of the compositions in the active layer 178 and raise the overall bandgap, thereby reducing carrier diffusion to the sidewalls 175 and overall non-radiative recombination. Such a process may be performed at elevated temperatures, and may include an additional anneal at elevated temperatures, such as greater than 500° C.

Referring now to FIGS. 4B-4C two different regrowth options are illustrated in which a sidewall passivation layer 172 is grown on the sidewalls 175 and lattice matched with the sidewalls 175. In the embodiment illustrated in FIG. 4B, regrowth is performed around and underneath the bottom doped layer 174. In the embodiment illustrated in FIG. 4C, regrowth is confined to the sidewalls 175. In either configuration the sidewall passivation layer 172 may be lattice matched with the micro-sized diodes 106 and satisfy dangling bonds at the sidewalls 175. In this manner, a sidewall passivation layer 172 with higher bandgap, or insulating qualities, compared to the quantum well layer(s) within the active layer 178 may reduce carrier diffusion past the sidewalls 175 and overall non-radiative recombination at the outside surface of the regrown sidewall passivation layer 172. In an embodiment, the sidewall passivation layer 172 is doped to the same conductivity as the bottom doped layer 174.

In each of FIGS. 4A-4C the diffused sidewall passivation layer 170 may be diffused into and the regrown sidewall passivation layer 172 can be grown on any combination of the active layer, n-doped layer, and p-doped layers. In the embodiment illustrated in FIG. 4A the diffused sidewall passivation layer can be diffused into and span across sidewalls of the p-doped layer (e.g. bottom doped layer 174) the active layer and the n-doped layer (e.g. top doped layer 176). In the embodiments illustrated in FIGS. 4B-4C the regrown passivation spans across sidewalls of the p-doped layer the active layer and the n-doped layer. In other embodiments the sidewall passivation layers can be selectively diffused into or grown onto the active layer, or combination with other layers forming the sidewalls.

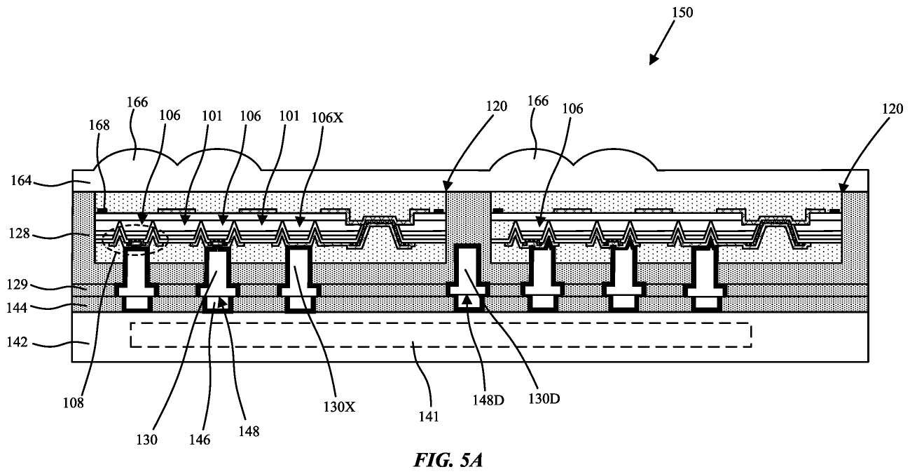

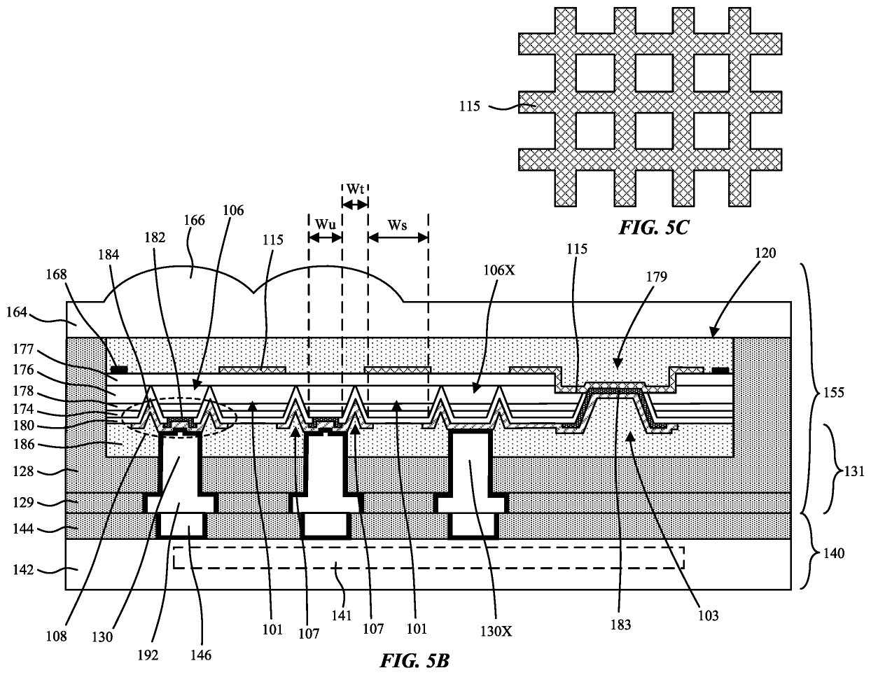

Referring now to FIGS. 5A-5C, FIG. 5A is a schematic cross-sectional side view illustration of an optoelectronic structure including multiple coupons in accordance with an embodiment; FIG. 5B is a close-up schematic cross-sectional side view illustration of an optoelectronic structure including a single coupon in accordance with an embodiment; FIG. 5C is a schematic top view illustration of the top opaque electrode layer of FIG. 4B in accordance with an embodiment. The embodiment illustrated in FIG. 5A shares many general features of the embodiment illustrated and described with regard to FIG. 3. Accordingly, the following description is made with regard to structural differences and may be aided by the close-up illustrates of FIGS. 5B-5C.

As shown in FIGS. 5A-5B, in the particular embodiment illustrated the landing pads 108 may be integrated into the corresponding reflector layers 184. This may be achieved by further integrating a pattern of intermediate p-n diode layer material 101 laterally between the micro-sized diodes 106 of the sub-arrays of micro-sized diodes, where the micro-sized diodes 106 are defined by trenches 107 at least partially through the p-n diode layer 102. The trenches 107 additionally separate the intermediate p-n diode layer material 101 from the micro-sized diodes 106. Furthermore, the reflector layers 184 wrap conformally around the corresponding micro-sized diodes 106 and a portion of the adjacent pattern of intermediate p-n diode layer material 101. Such a configuration may provide several structural attributes. In one aspect, the reflector layers 184 also serve as the land pads 108 for via contacts 130. As shown in FIG. 5A, the reflector layers 184 for a mis-aligned coupon 120M can be wider than the via contacts 130 and allow for landing of the via contacts 130 for a mis-align coupon 120. For example, the via contacts 130 can optionally partially or fully overlap a portion of a trench 107. In another aspect the volume of semiconductor material in the intermediate p-n diode layer material 101 can potentially improve planarity during wafer-to-wafer bonding of the device layer to the first carrier substrate 112.

Referring now to FIG. 5B, a supplemental via contact 130X is illustrated that can provide electrical connection between the working circuitry 141 of the backplane 140 and the top sides of the micro-sized diodes 106. As shown, the via contact 130X can optionally land on a reflector layer 184, or even one of the layers used to form the reflector layers 184. This may run through an opening 103 in and underside of the p-n diode layer 102 and make contact with an electrically conductive top electrode layer 115 on a top side of the p-n diode layer 102. The top electrode layer 115 may optionally be formed within an opening 179 in the top side of the p-n diode layer 102. Exemplary materials for top electrode layer 115 include metallic materials such as Ni, Ge, Al, Pt, Ru, Au, including metal stack-up combinations thereof, and alloys thereof. As such, the top electrode layer 115 may be opaque. As shown, the FIG. 5C, the top electrode layer 115 may be patterned into a mesh, or grid, configuration with openings over each micro-sized diode 106. In this way, the metallic materials forming the top electrode layer 115 are located above the intermediate p-n diode layer material 101 and do not absorb significant light emitted by the functional micro-sized diodes 106. Electrical connection can be facilitated by a doped current spreading layer 177 (e.g. n++ doped III-V material) within the p-n diode layer 102.

In the particular embodiment illustrated, the supplemental via contacts 130X can be landed on the reflector layers 184 on spare micro-sized diodes 106X. Such a configuration may enable the use of mask sets that support a combination of LED redundancy, or spares, both physically and electrically while also supporting use of the same masks for top side contact connection. For example, the individual micro-sized diodes may be optically tested at an intermediate stage during fabrication to determine any irregularities. At such a time, a decision can be made as to whether to utilize the spare micro-sized diodes 106X instead for emissive micro-sized diodes 106 with via contact 130 connection, or as a support structure for the supplemental via contacts 130X. The result of this decision can determine whether to pattern the dielectric insulation layer 180 and form bottom electrical contacts 182 or not. Where dielectric insulation layer 180 is not patterned and bottom electrical contacts 182 are not formed, the supplemental via contacts 130X do not make electrical contact with the spare micro-sized diodes 106X upon which they are landed. It is to be appreciated that supplemental via contacts 130X can instead be landed on the intermediate p-n diode layer material 101. Additionally, such structure can be implemented in other optoelectronic structures described herein, inclusive of FIG. 3 and the related description and figures.

In an embodiment, the array of via contacts 130 (and supplemental via contacts 130X) extends through a portion of the gap fill layer 128, though this is not required. As shown in FIGS. 5A-5B, in an embodiment the coupons 120 can include a p-n diode layer that includes a corresponding sub-array of micro-sized diodes 106 (which can include spare micro-sized diodes 106X), and a pattern of intermediate p-n diode layer material 101 laterally between the micro-sized diodes 106 of the sub-array of micro-sized diodes, where the pattern of intermediate p-n diode layer material 101 is separated from the sub-array of micro-sized diodes 106 by trenches 107. As shown in FIG. 5B, a minimum width (Ws) of the pattern of intermediate p-n diode layer material 101 positioned laterally between immediately adjacent micro-sized diodes 106 of the sub-array of micro-sized diodes may be greater than a minimum width (Wu) of the immediately adjacent micro-sized diodes 106. The maximum trench 107 width (Wt) can be tailored to device density, and layer thickness of the layers to be formed therein, such as dielectric insulation layer 180 and reflector layer 184. In accordance with embodiment, the coupons 120 can include a sub-array of reflector layers 184 wrapping conformally around the sub-array of micro-sized diodes 106 (inclusive of the spare micro-sized diodes 106X) and a portion of the pattern of intermediate p-n diode layer material 101. Each reflector layer 184 may include, or correspond to, a landing pad 108 of the array of landing pads.

Still referring to FIGS. 5A-5B, in an embodiment the optoelectronic structure 150 includes an opaque top electrode layer 115 spanning over the pattern of intermediate p-n diode layer material 101. An opening 103 can be formed through a back side of the p-n diode layer, and a back side contact layer 183 is formed within the opening and in electrical contact with the top electrode layer 115. The back side contact layer 183 may be formed of a variety of materials including the same layers used to form bottom electrical contact 182 or reflector layer 184. The back side contact layer 183 may also be a discrete layer of different composition and thickness than the surrounding electrically conductive layers. In accordance with embodiments, the back side contact layer 183 is electrically connected with a supplemental via contact 130X that is bonded with a contact pad 148 of the array of contact pads 148 of the backplane 140. The supplemental via contact 130X may additionally be connected to a reflector layer 184, which is in turn connected with the back side contact layer 183. A variety of possibilities are envisioned for electrically connecting the backplane 140 with the top electrode layer 115.

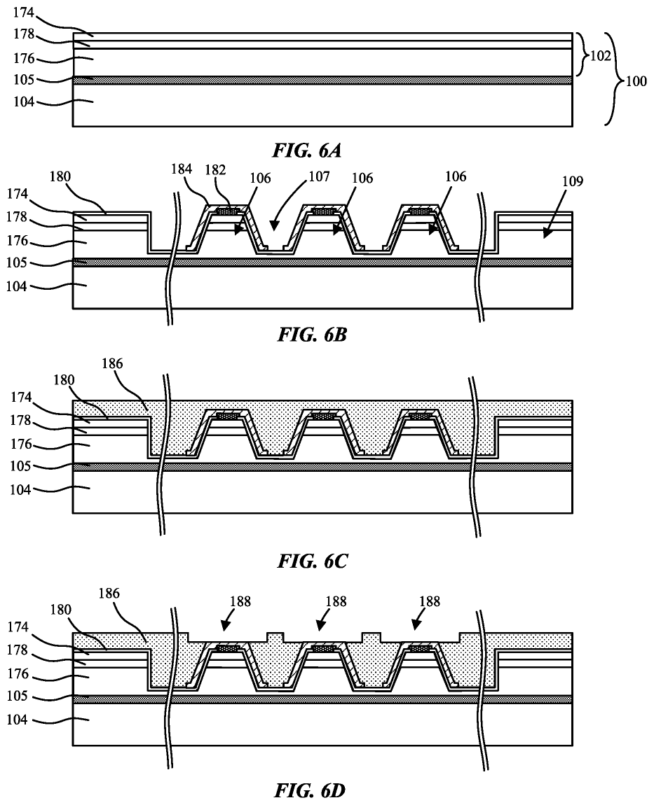

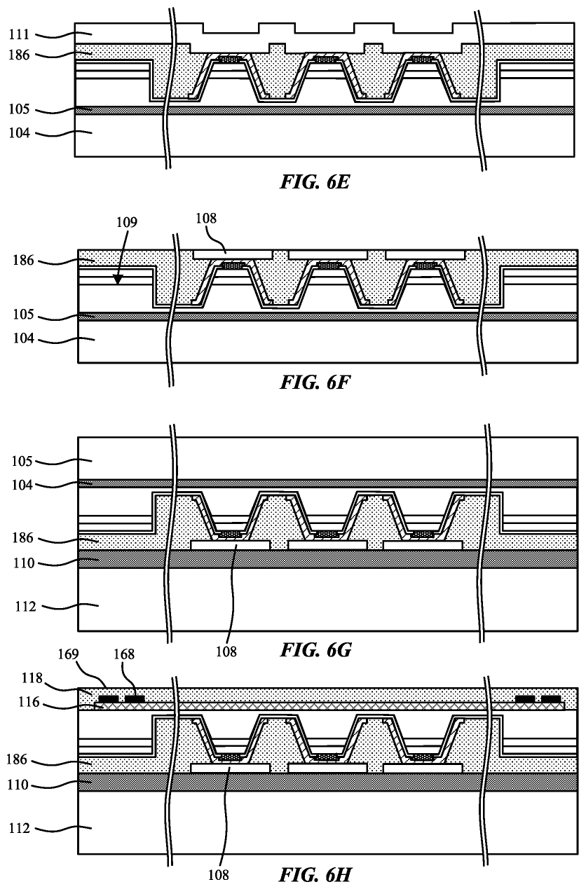

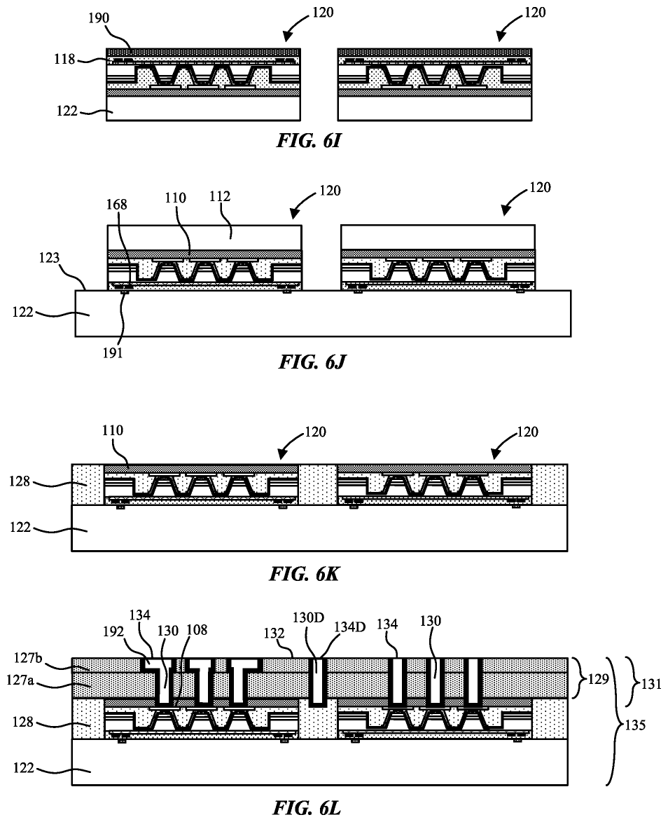

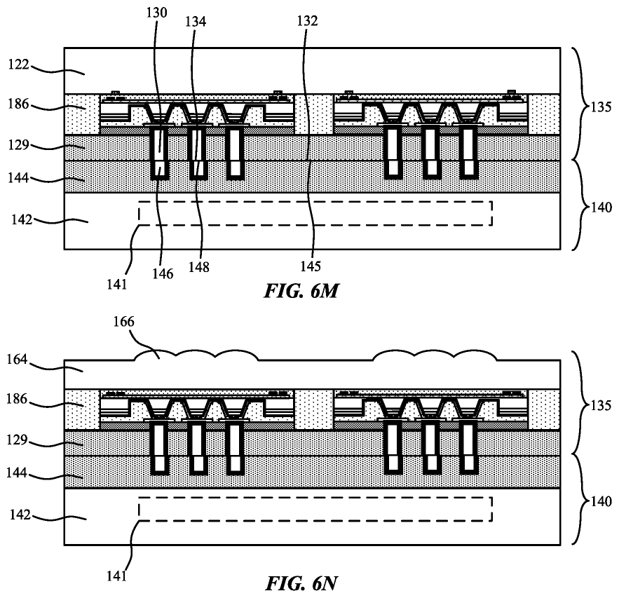

FIGS. 6A-6N are cross-sectional side view illustrations of a micro-sized diode reconstitution and wafer-to-wafer bonding sequence in accordance with an embodiment. FIGS. 6A-6N are complementary with and supplemental to the sequence illustrated in FIG. 1 and optoelectronic structure 150 of FIG. 3. As shown in FIG. 6A, the sequence may begin with a bulk LED substrate 100 including a p-n diode layer 102 including a bottom doped layer 174 (e.g. p-doped), a top doped layer 176 (e.g. n-doped) with an opposite doping than the bottom doped layer, and an active layer 178 between the bottom doped layer and the top doped layer.

By way of example, in an embodiment the p-n diode layer 102 is designed for emission of red light, and the materials are phosphorus based. The followed listing of materials for red emission is intended to be exemplary and not limiting. For example, the layers forming the p-n diode layer 102 may include AlInP, AlInGaP, AlGaAs, GaP, and GaAs. In an embodiment, top doped layer 176 includes n-AlInGaP and bottom doped layer 174 includes p-AlGaInP. Active layer 178 may be formed of a variety of materials, such as but not limited to, AlGaInP, AlGaAs, and InGaP. In such an embodiment, a suitable growth substrate 104 may include, but not limited to, silicon, SiC, and GaAs. A sacrificial layer 105 may be formed of suitable buffer material, such as AlGaInP may be formed for subsequent removal.

By way of example, in an embodiment, the p-n diode layer 102 is designed for emission of blue or green light, and the materials are nitride based. The followed listing of materials for blue or green emission is intended to be exemplary and not limiting. For example, the layers forming the p-n diode layer 102 may include GaN, AlGaN, InGaN. In an embodiment, top doped layer 176 includes n-AlGaN and bottom doped layer 174 includes p-AlGaN. Active layer 178 may be formed of a variety of materials, such as but not limited to, InGaN. In such an embodiment, a suitable growth substrate 104 may include, but is not limited to, silicon and sapphire. A sacrificial layer 105 may be formed of suitable buffer material, such as AlGaN may be formed for subsequent removal.

Referring now to FIG. 6B the p-n diode layer 102 is etched to form an array of micro-sized diodes 106 separated by trenches 107. A pattern of walls 109 may optionally remain. Walls 109 may not be active diode regions, though may be kept in the structure to provide mechanical stability for example. Walls 109 may be formed around the perimeter of the patterned bulk LED substrate 100 or remain at strategic locations that may end up in the display/detection area of the optoelectronic structure. Following formation of the micro-sized diodes 106 additional sidewall passivation processing may optionally be performed as described with FIGS. 4A-4C, followed by deposition of a dielectric insulation layer 180 (e.g. Al₂O₃, SiO₂, etc.). The dielectric insulation layer 180 may then be patterned to expose the p-n diode layer 102, followed by deposition of the bottom electrical contact 182 and reflector layer 184.

In the particular embodiment illustrated in FIG. 6B the etching of the p-n diode layer 102 is not completely through the top doped layer 176, which may optionally remain connected between the micro-sized diodes 106. However, this is exemplary, and in other embodiments etching of the p-n diode layer 102 is completely through the top doped layer 176 to completely separate the micro-sized diodes 106 (similar to the illustrations in FIG. 1).

A dielectric fill layer 186 may be formed around and over the micro-sized diodes 106 as shown in FIG. 6C. The dielectric fill layer 186 may be formed of a suitable material such as silicon dioxide, silicon nitride, SiCₓN_{y}O_{z}, BCB, epoxy, acrylic, etc. and may be transparent or opaque. For example, the dielectric fill layer 186 may be deposited using a solvent based technique such as slot coating or spin coating. Other suitable deposition techniques can also be used for other materials, such as plasma-enhanced chemical vapor deposition (PECVD) or physical vapor deposition (PVD), followed by CMP planarization. The dielectric fill layer 186 may then be patterned to form openings 188 as shown in FIG. 6D that expose the reflector layers 184 when present or alternatively another electrical connector (e.g. bottom contact 182) for the micro-sized diodes 106.

Referring now to FIG. 6E a bulk metal layer 111 is deposited over the underlying structure. For example, this may be accomplished by plating. The bulk metal layer 111 may include one or more layers of materials such as Ta, TaN and W. The bulk metal layer 111 may be thick enough to completely fill the openings 188. This may be followed by a planarization operation, for example CMP, to remove any remaining bulk metal layer 111 outside of the openings 188, resulting in landing pads 108 as shown in FIG. 6F. In an embodiment, the gap fill layer 186 optionally covers the walls 109 after planarization.

Referring to FIG. 6G the planarized surface can then be capped with a backside dielectric layer 110 (e.g. SiO₂ film) and then planarized and bonded to a first carrier substrate 112 with a dielectric-dielectric (oxide-oxide) bond. Such a processing sequence is consistent with operation 1020A of FIG. 1, though the processing sequence of operation 1020B may also be utilized.

The growth substrate 104 and sacrificial layer 105 may then be removed as shown in FIG. 6H followed by the formation of the top contact layer 116 metal alignment keys 168 for die-to-wafer bonding. Various routing layers may also be deposited at this point. The alignment keys 168 may optionally be deposited and patterned with a lift-off technique. A protective dielectric layer 118 may then be deposited and planarized to form planar surface 169.

As shown in FIG. 6I a protective coating 190 can then be deposited over the protective dielectric layer 118, followed by substrate thinning and dicing into individual coupons 120. Such a coating may help prevent particles from adhering to the coupon 120 surfaces Exemplary coatings can include solvent/water cleanable films such as polymethyl methacrylate (PMMA), water soluble resins, etc.

In accordance with embodiments, the protective coating 190 can be removed followed by testing of known good dies (KGD) or coupons 120. Thus, KGD testing may be performed after singulation illustrated in FIG. 6I. KGD testing may also be performed prior to singulation in FIG. 6H. In both implementations KGD testing may be performed after removal of the growth substrate, such that the epitaxial device layers are on a first carrier substrate 112 (e.g. silicon carrier). In this manner, the process flow allows for the option of only KGD coupons to be reconstituted, and in particular KGD coupons on silicon rather than a growth substrate that is CTE mis-matched with silicon.

Referring now to FIG. 6J the coupons 120 may be bonded to a top surface 123 of a second carrier substrate 122. Bonding may be die-to-wafer bonding process including coupon cleaning, coupon plasma activation, top surface 123 activation, and dielectric-dielectric (oxide-oxide) bonding. As shown, the alignment keys 168 of the coupons 120 may be aligned with registration marks 191 on the second carrier substrate 122, which can be formed using suitable techniques such as etch marks into a silicon substrate or deposition of metal marks on a silicon substrate, followed by dielectric (oxide) fill and CMP to form top surface 123.

A gap fill layer 128 may then be deposited over the second carrier substrate 122 and coupons 120 filling the lateral spaces between the coupons 120, and laterally surrounding the coupons 120. The gap fill layer 128 may be an oxide layer or other suitable dielectric, including polymer. This may be followed by a planarization operation, which may remove the second carrier substrate 122 portions and expose the backside dielectric layers 110 of the coupons, as depicted in FIG. 6K.

Referring now to FIG. 6L the partially reconstituted substrate can be processed with industry-standard 300 mm copper damascene processing to form one or more metal layers (including two or more metal layers). In interest of illustration, a single metal layer is illustrated with both single damascene and dual damascene options. It is to be appreciated this is for illustrational purposes only, and a variety of routing options are available. In both processes, the via contacts 130 are formed to connect with the landing pads 108. As shown, a dielectric build-up layer 129 can be formed over the gap fill layer 128 and coupons 120. The dielectric build-up layer 129 can include one or more dielectric layers 127a, 127b, etc. as well as one or more metal (e.g. Cu) layers for redistribution lines and vias forming the reconstituted wiring layer 131. The redistribution lines and vias of the reconstituted wiring layer 131 may be formed using a single damascene process with trench 192 and via 130 formation as two metal layers, or dual damascene manner (as illustrated) with trench 192 and via 130 formation as a single metal layer. As previously described, the damascene process is decoupled from coupon 120 placement by inclusion of the oversized landing pads. Following the damascene processing the reconstituted substrate 135 can be planarized to provide planar dielectric surface 132 and planar contact surface 134 of the metal layers.

Still referring to FIG. 6L, in accordance with embodiments dummy vias 130D (and optionally dummy trenches) can be formed, optionally including dummy planar contact surfaces 134D. The plurality of dummy vias 130D may be arranged between the coupons so that they do not vertically overlap with the plurality of coupons 120. This may facilitate mechanical and thermal balancing for example, though other arrangements are possible. The dummy planar contact surfaces 134D may also improve topography to facilitate metal-metal (copper-copper) bonding to the backplane. As described with regard to FIG. 1, the oversized landing pads 108 can decouple damascene processing and eventual wafer-to-wafer alignment from coupon 120 placement.

The reconstituted substrate 135 may then be bonded to a backplane 140, such as a CMOS substrate, as shown in FIG. 6M. In accordance with embodiments, the bonding may be wafer-to-wafer hybrid bonding using copper-to-copper metallic interconnects. The backplane 140 may include a silicon substrate 142 and top dielectric layer 144 with vias 146. A top surface may be planarized to form planarized top contact pads 148 of the vias 146 and planarized top surface 145 of the top dielectric layer 144. In an embodiment, hybrid bonding may achieve metal-metal (e.g. copper-copper) bonds with contact pads 148 and planar contact surfaces 134, and dielectric-dielectric (e.g. oxide-oxide) bonds with planar dielectric surface 132 and top surface 145 of top dielectric layer 144. The second carrier substrate 122 can then be removed using a suitable technique such as wafer grind followed by CMP, or wafer grind followed by a wet chemical etch process.

Final power and data routing circuitry may then be added, as well as any optical structures such as a micro lens array as shown in FIG. 6N. For example, an optical layer 164 such as a transparent polymer can be deposited followed by imprinting to form half ball features 166 or similar. Individual optoelectronic structures 150 may then be singulated from the stack-up.

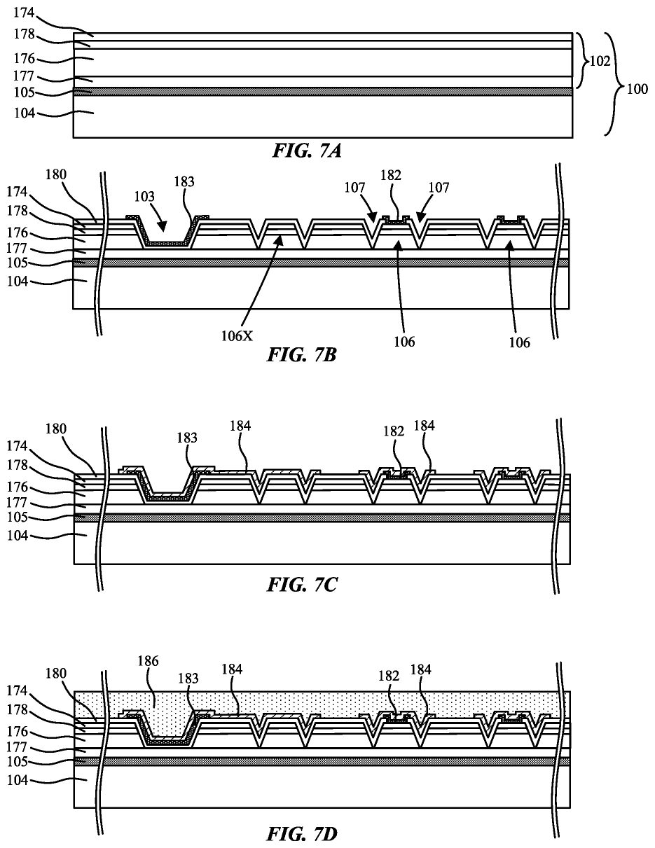

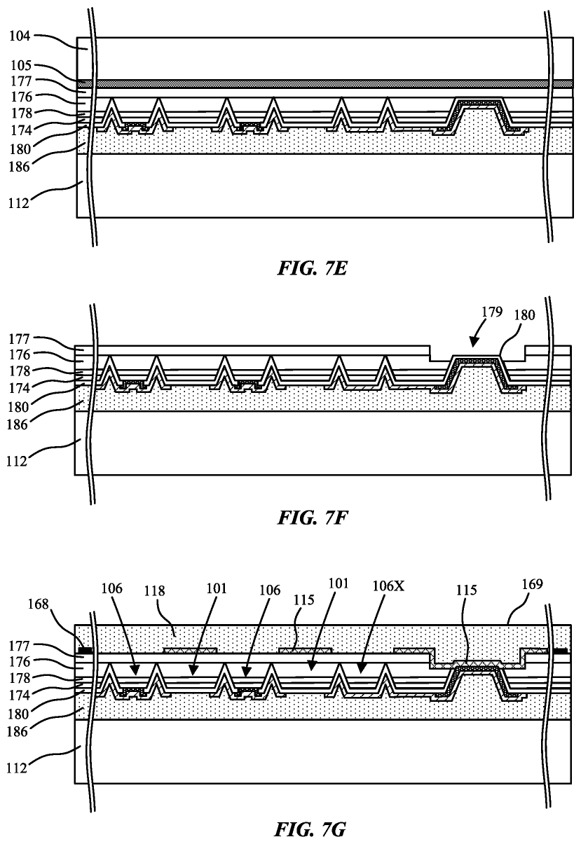

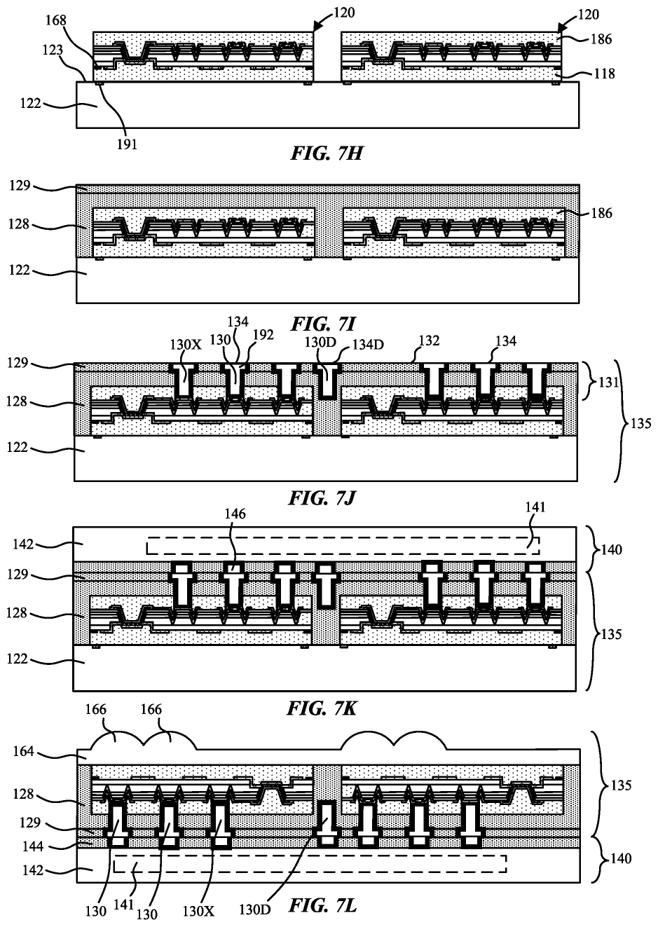

FIGS. 7A-7L are cross-sectional side view illustrations of a micro-sized diode reconstitution and wafer-to-wafer bonding sequence in accordance with an embodiment. FIGS. 7A-7L bear similarities to the sequences illustrated in FIG. 1 and FIGS. 6A-6N with some modifications to achieve the optoelectronic structures illustrated and described with regard to FIGS. 5A-5C. As shown in FIG. 6A, the sequence may begin with a bulk LED substrate 100 including a p-n diode layer 102 including a bottom doped layer 174 (e.g. p-doped), a top doped layer 176 (e.g. n-doped) with an opposite doping than the bottom doped layer, and an active layer 178 between the bottom doped layer and the top doped layer. The p-n diode layer 102 may optionally include a current spreading layer 177 (e.g. n++ doped) that may be doped with similar dopant type as top doped layer 176 (and optionally more highly doped). For example, current spreading layer 177 may be formed of a similar material as top doped layer 176. Similar to previous descriptions the p-n diode layer 102 may be designed for emission of red light, green light, blue light, etc.

Referring now to FIG. 7B the p-n diode layer 102 is etched to form an array of micro-sized diodes 106, and optional spare micro-sized diodes 106, separated by trenches 107. Opening(s) 103 may additionally be formed to facilitate back side contact. In the particular embodiment illustrated in FIG. 7B the etching of the p-n diode layer 102 is not completely through the current spreading layer 177 which may optionally remain connected between the micro-sized diodes 106. However, this is exemplary, and in other embodiments etching of the p-n diode layer 102 is completely through the current spreading layer 177 to completely separate the micro-sized diodes 106. A pattern of walls may remain as shown by the pattern of intermediate p-n diode layer material 101 to provide mechanical stability for example. Following formation of the micro-sized diodes 106, optional spare micro-sized diodes 106, and the pattern of intermediate p-n diode layer material 101 additional sidewall passivation processing may optionally be performed as described with FIGS. 4A-4C, followed by deposition of a dielectric insulation layer 180 (e.g. Al2O3, SiO2, etc.). The dielectric insulation layer 180 may then be patterned to expose the p-n diode layer 102, followed by deposition of the bottom electrical contacts 182 and reflector layers 184. As shown in FIG. 7B, back side contact layer 183 may be deposited in the openings 103 simultaneously with, concurrently with, or separately from the bottom electrical contacts 182, and may share the same layer stack-up, partial layers, or be a completely different layer(s). As shown in FIG. 7C, the reflector layers may be formed over the bottom electrical contacts 182 and back side contact layer 183, as well as within the trenches 107 and span partially over portions of the p-n diode layer material 101.

A dielectric fill layer 186 may be formed around and over the micro-sized diodes 106 as shown in FIG. 7D. The dielectric fill layer 186 may be formed of a suitable material such as silicon dioxide, silicon nitride, SiCxNyOz, BCB, epoxy, acrylic, etc. and may be transparent or opaque. For example, the dielectric fill layer 186 may be deposited using a solvent based technique such as slot coating or spin coating. Other suitable deposition techniques can also be used for other materials, such as plasma-enhanced chemical vapor deposition (PECVD) or physical vapor deposition (PVD), followed by CMP planarization.

Referring to FIG. 7E the planarized surface can then be bonded to a first carrier substrate 112 with a dielectric-dielectric (oxide-oxide) bond. The growth substrate 104 and sacrificial layer 105 may then be removed as shown in FIG. 7F followed by formation of opening(s) 179 in the p-n diode layer over the back side contact layer 183, and underlying opening 103. As shown, etching of the openings 179 may stop on the dielectric insulation layer 180. A second operation may then be performed to selectively remove the dielectric insulation layer 180 within the openings 179 exposing the back side contact layer 183. This may be followed by formation of the top electrode layer 115, metal alignment keys 168 for die-to-wafer bonding, and protective dielectric layer 118 as shown in FIG. 7G. The protective dielectric layer 118 may then be planarized to form planar surface 169.

In accordance with embodiments KGD testing may be performed prior to formation of the protective dielectric layer 118 and prior to singulation into coupons. KGD testing may also be performed after singulation. In this manner, the process flow allows for the option of only KGD coupons to be reconstituted, and in particular KGD coupons on silicon rather than a growth substrate that is CTE mis-matched with silicon.

Referring now to FIG. 7H the coupons 120 may be bonded to a top surface 123 of a second carrier substrate 122. Bonding may be die-to-wafer bonding process including coupon cleaning, coupon plasma activation, top surface 123 activation, and dielectric-dielectric (oxide-oxide) bonding. As shown, the alignment keys 168 of the coupons 120 may be aligned with registration marks 191 on the second carrier substrate 122, which can be formed using suitable techniques such as etch marks into a silicon substrate or deposition of metal marks on a silicon substrate, followed by dielectric (oxide) fill and CMP to form top surface 123.

A gap fill layer 128 may then be deposited over the second carrier substrate 122 and coupons 120 filling the lateral spaces between the coupons 120, and laterally surrounding the coupons 120 as shown in FIG. 7I. The gap fill layer 128 may be an oxide layer or other suitable dielectric, including polymer. In the particular embodiment illustrated the gap fill layer 128 covers the dielectric fill layer 186 for each of the coupons 120, though this is optional. Additionally, a dielectric build-up layer 129 can be formed over the gap fill layer 128 and coupons 120. The dielectric build-up layer 129, for example may be utilized in a dual damascene process, though embodiments are not so limited.

Referring now to FIG. 7J the partially reconstituted substrate can be processed with industry-standard 300 mm copper damascene processing to form one or more metal layers (including two or more metal layers) 131 as part of a reconstituted wiring layer 131. Similar to previous discussion single damascene and dual damascene fabrication sequences can be used, for example. In the particular embodiment illustrated dual damascene processing is shown, though this is not required. It is to be appreciated this is for illustrational purposes only, and a variety of routing options are available. In both processes, the via contacts 130 are formed to connect with the landing pads 108 formed by the reflector layers 184. As previously described, the damascene processes is decoupled from coupon 120 placement by inclusion of the oversized landing pads formed by the reflector layers 184. Following the damascene processing the reconstituted substrate 135 can be planarized to provide planar dielectric surface 132 and planar contact surface 134 of the metal layers.

Still referring to FIG. 7J, in accordance with embodiments dummy vias 130D (and optionally dummy trenches) can be formed, optionally including dummy planar contact surfaces 134D. The plurality of dummy vias 130D may be arranged between the coupons so that they are not directly above the plurality of coupons 120. This may facilitate mechanical and thermal balancing for example, though other arrangements are possible. The dummy planar contact surfaces 134D may also improve topography to facilitate metal-metal (copper-copper) bonding to the backplane.

The reconstituted substrate 135 may then be bonded to a backplane 140, such as a CMOS substrate or substrate with embedded pixel driver chips, as shown in FIG. 7K. In accordance with embodiments, the bonding may be wafer-to-wafer hybrid bonding using copper-to-copper metallic interconnects. The backplane 140 may include a silicon substrate 142 and top dielectric layer 144 with vias 146. A top surface may be planarized to form planarized top contact pads 148 of the vias 146 and planarized top surface 145 of the top dielectric layer 144. In an embodiment, hybrid bonding may achieve metal-metal (e.g. copper-copper) bonds with contact pads 148 and planar contact surfaces 134, and dielectric-dielectric (e.g. oxide-oxide) bonds with planar dielectric surface 132 and top surface 145 of top dielectric layer 144. The second carrier substrate 122 can then be removed using a suitable technique such as wafer grind followed by CMP, or wafer grind followed by a wet chemical etch process.

Final power and data routing circuitry may then be added, as well as any optical structures such as a micro lens array as shown in FIG. 7L. For example, an optical layer 164 such as a transparent polymer can be deposited followed by imprinting to form half ball features 166 or similar. Individual optoelectronic structures 150 may then be singulated from the stack-up.

In utilizing the various aspects of the embodiments, it would become apparent to one skilled in the art that combinations or variations of the above embodiments are possible for forming an optoelectronic structure. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. An optoelectronic structure comprising:
a backplane including driving circuitry and an array of contact pads;
a device layer bonded to the backplane, the device layer including:
an array of micro-sized diodes;
an array of landing pads underneath the array of micro-sized diodes, each landing pad corresponding to a micro-sized diode; and
an array of via contacts connected to the array of landing pads, each via contact corresponding to a landing pad;
wherein the array of via contacts is part of a reconstituted wiring layer that is directly bonded with the array of contact pads with metal-metal bonds.

2. The optoelectronic structure of claim 1, wherein the array of via contacts is a damascene array.

3. The optoelectronic structure of claim 1, wherein the array of via contacts is at least partially embedded within a dielectric build-up layer.

4. The optoelectronic structure of claim 3, wherein the dielectric build-up layer is bonded directly to a top dielectric layer of the backplane.

5. The optoelectronic structure of claim 1, wherein the array of micro-sized diodes is comprised of a plurality of coupons, each coupon including a sub-array of micro-sized diodes.

6. The optoelectronic structure of claim 5, wherein each coupon includes a dielectric fill layer underneath a corresponding sub-array of micro-sized diodes, and the array of via contacts includes a plurality of sub-arrays of via contacts, and each sub-array of via contacts extends through a corresponding dielectric fill layer.

7. The optoelectronic structure of claim 6, wherein a pitch between the via contacts within each sub-array of via contacts is 5 μm or less.

8. The optoelectronic structure of claim 5, further comprising a gap fill layer laterally surrounding each coupon and laterally between adjacent coupons.

9. The optoelectronic structure of claim 8, wherein the array of via contacts extends through a portion of the gap fill layer.

10. The optoelectronic structure of claim 8, wherein a coupon of the plurality of coupons includes a p-n diode layer comprising:
a corresponding sub-array of micro-sized diodes;
a pattern of intermediate p-n diode layer material laterally between the micro-sized diodes of the sub-array of micro-sized diodes;
wherein the pattern of intermediate p-n diode layer material is separated from the sub-array of micro-sized diodes by trenches.

11. The optoelectronic structure of claim 10, wherein a minimum width of the pattern of intermediate p-n diode layer material laterally between immediately adjacent micro-sized diodes of the sub-array of micro-sized diodes is greater than a minimum width of the immediately adjacent micro-sized diodes.

12. The optoelectronic structure of claim 10, wherein:
the coupon further comprises a sub-array of reflector layers wrapping conformally around the sub-array of micro-sized diodes and a portion of the pattern of intermediate p-n diode layer material;
and each reflector layer includes a corresponding landing pad of the array of landing pads.

13. The optoelectronic structure of claim 10, further comprising an opaque top electrode layer spanning over the pattern of intermediate p-n diode layer material.

14. The optoelectronic structure of claim 13, further comprising an opening through the p-n diode layer, and a back side contact layer within the opening and in electrical contact with the top electrode layer.

15. The optoelectronic structure of claim 14, wherein the back side contact layer is electrically connected with a supplemental via contact that is electrically connected with a contact pad of the array of contact pads.

16. The optoelectronic structure of claim 15, wherein the supplemental via contact is connected to a reflector layer of the sub-array of reflector layers.

17. The optoelectronic structure of claim 5, wherein a placement distribution of the array of landing pads across the backplane is characterized by a first order standard deviation of displacement values of the array of landing pads to the array of contact pads, and position distribution of the array of via contacts across the backplane is characterized by a first order standard deviation of displacement values of the array of via contacts to the corresponding array of contact pads, and the first order standard deviation for the placement distribution of the array of landing pads across the backplane is larger than the first order standard deviation for the position distribution of the array of via contacts across the backplane.

18. The optoelectronic structure of claim 5, further comprising a plurality of dummy vias adjacent the array of via contacts.

19. The optoelectronic structure of claim 18, wherein the plurality of dummy vias does not vertically overlap with the plurality of coupons.

20. The optoelectronic structure of claim 1, wherein the micro-sized diodes of the array of micro-sized diodes are light emitting diodes (LEDs).

21. The optoelectronic structure of claim 1, wherein the micro-sized diodes of the array of micro-sized diodes are photodetectors (PD).

22. The optoelectronic structure of claim 1, wherein the driving circuitry includes CMOS driving circuitry.

23. The optoelectronic structure of claim 1, wherein the driving circuitry includes an array of pixel driver chips.

24. The optoelectronic structure of claim 1, wherein the micro-sized diodes includes a sub-array of regrown micro-size diodes, each regrown micro-sized diode including a p-doped layer, an n-doped layer, an active layer between the p-doped layer and the n-doped layer, and a regrown layer spanning across sidewalls of the p-doped layer the active layer and the n-doped layer.

25. A method of assembling an optoelectronic structure comprising:
patterning an array of micro-sized diodes into a p-n diode layer on a growth substrate;
forming an array of landing pads on top of the array of micro-sized diodes;
transferring the array of micro-sized diodes and the array of landing pads to a first carrier substrate;
singulating the array of micro-sized diodes, the array of landing pads, and the first carrier substrate into a plurality of coupons, each coupon including a sub-array of micro-sized diodes and sub-array of landing pads;
reconstituting an array of coupons on a second carrier substrate to form a reconstituted substrate;
hybrid bonding the reconstituted substate to a backplane; and
singulating a plurality of optoelectronic structures.

26. The method of claim 25, wherein the first carrier substrate, the second carrier substrate, and the backplane each comprises a silicon wafer.

27. The method of claim 25, wherein reconstituting the array of coupons on the second carrier substrate comprise die-to-wafer bonding the array of coupons to the second carrier substrate.

28. The method of claim 27, wherein hybrid bonding the reconstituted substrate to the backplane comprises wafer-to-wafer bonding.

29. The method of claim 25, wherein the backplane comprises CMOS driving circuitry.
